(19) United States
(12) Patent Application Publication
(10) Pub. No.: US 2020/0273988 A1
(43) Pub. Date: Aug. 27, 2020

(54) SEMICONDUCTOR DEVICE

(71) Applicant: TOYODA GOSEI CO., LTD., Kiyosu-shi (JP)

(72) Inventor: Tsutomu INA, Kiyosu-shi (JP)

(21) Appl. No.: 16/793,949

(22) Filed: Feb. 18, 2020

(30) Foreign Application Priority Data
Feb. 22, 2019 (JP) 2019-030652

(51) Int. Cl. H01L 29/78; H01L 29/20; H01L 29/06; H01L 29/10

(52) U.S. Cl. CPC H01L 29/7813; H01L 29/1095; H01L 29/063; H01L 29/2003

(57) ABSTRACT

To provide a semiconductor device having a lower on-resistance while keeping a sufficient high breakdown voltage. A semiconductor device comprises a conductive substrate, a first semiconductor layer, a second semiconductor layer, a third semiconductor layer, a fourth semiconductor layer, a body electrode, a drain electrode, a source electrode, and a gate electrode. The first semiconductor layer, the second semiconductor layer, the third semiconductor layer, and the fourth semiconductor layer are Group III nitride semiconductor layers. The third semiconductor layer has a carrier concentration lower than that of the second semiconductor layer.

### BACKGROUND OF THE INVENTION

### Field of the Invention

The present invention relates to a semiconductor device having a gate electrode.

### Background Art

Group III nitride semiconductor represented by GaN has high dielectric breakdown electric field and high melting point. Therefore, Group III nitride semiconductor is expected as the material for high-power, high-frequency, and high-temperature resistance semiconductor device, instead of GaAs-based semiconductor. A HEMT (High Electron Mobility Transistor) using Group III nitride semiconductor has been researched and developed.

For example, Japanese Patent Application Laid-Open (kokai) No. 2011-082397 discloses techniques for forming a p-side electrode that is in ohmic contact with the p-type GaN-based semiconductor layer (paragraph [0007]). Moreover, it discloses that the p-side electrode can attract holes in the p-type GaN-based semiconductor layer and extract the holes to the outside (paragraph [0007]).

A semiconductor device such as vertical FET (Field effect transistor) is required to have a high breakdown voltage and a low on-resistance. The on-resistance is defined as resistance between a source and a drain at on state of FET. Breakdown voltage is mainly determined by the dielectric breakdown voltage in reverse-biased pn junction. The lower the on-resistance, the larger the current can be made to flow in the semiconductor device.

### SUMMARY OF THE INVENTION

In view of the foregoing, an object of the present invention is to provide a semiconductor device having a low on-resistance while keeping a high breakdown voltage.

In a first aspect of the present invention, there is provided a semiconductor device including a gate electrode formed comprising:

a first semiconductor layer with a first conduction type;

a second semiconductor layer with a second conduction type formed on the first semiconductor layer, the second conduction type being opposite to the first conduction type;

a third semiconductor layer with the second conduction type formed on the second semiconductor layer;

a fourth semiconductor layer with the first conduction type formed on the third semiconductor layer, respective semiconductor layers from the first to the fourth semiconductor layer including Group III nitride semiconductor;

a first electrode contacted with at least one of the second semiconductor layer and the third semiconductor layer;

a second electrode for the first semiconductor layer; and

a third electrode for the fourth semiconductor layer,

wherein the second semiconductor layer and the third semiconductor layer induce or eliminate a channel by a gate voltage at side walls thereof near the gate electrode, and a carrier concentration of the third semiconductor layer is lower than a carrier concentration of the second semiconductor layer. In the semiconductor device according to the first aspect of the present invention, the carrier concentration of the third semiconductor layer may be not more than 0.6 times the carrier concentration of the second semiconductor layer.

In the semiconductor device according to the first aspect of the present invention, the semiconductor device may comprises a recess passing through the fourth semiconductor layer and reaching at least one of the second semiconductor layer and the third semiconductor layer. And the first electrode may be formed in the recess. The semiconductor device comprises a conductive substrate with first conduction type. And the first semiconductor layer may be formed on the conductive substrate.

In the semiconductor device according to the first aspect of the present invention, an impurity concentration of the third semiconductor layer may be lower than an impurity concentration of the second semiconductor layer. The third semiconductor layer may comprise a first conduction type impurity and a second conduction type impurity. And the second conduction type impurity concentration may be higher than the first conduction type impurity concentration.

In the semiconductor device according to the first aspect of the present invention, the first electrode may be in contact with both the second semiconductor layer and the third semiconductor layer.

In the semiconductor device according to the first aspect of the present invention, the gate electrode may be formed in a trench passing through the fourth semiconductor layer, the third semiconductor layer, and the second semiconductor layer, and reaching the middle of the first semiconductor layer.

In the semiconductor device according to the first aspect of the present invention, the second electrode may be contacted with at least one of on a back surface of the conductive substrate and the first semiconductor layer. Also each of the third semiconductor layer and the second semiconductor layer may have a uniform thickness and a flat surface. And the impurity concentration of the third semiconductor layer preferably has a uniform concentration in an entire area of the third semiconductor layer. Also a thickness of the third semiconductor layer is preferably any value from 0.01 μm to 0.5 μm.

The semiconductor device has a third semiconductor layer with an impurity concentration lower than that of the second semiconductor layer. Since the carrier concentration of the third semiconductor layer is low, electrons tend to be collected in the vicinity of a gate electrode. Therefore, the semiconductor device has an on-resistance lower than that of the conventional semiconductor device. There is no risk of lowering the breakdown voltage.

The present invention, disclosed in the specification, provides a semiconductor device having a lower on-resistance while keeping a sufficient breakdown voltage.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a schematic view of the structure of a semiconductor device of a first embodiment;

FIG. 2 is a graph showing the relationship between impurity concentrations of second semiconductor layer and third semiconductor layer in the first embodiment;

FIG. 3 is a schematic view illustrating on-resistance and breakdown voltage in the semiconductor device of the first embodiment;

FIG. 4 is a graph showing the relationship between the impurity concentrations of the second semiconductor layer and the third semiconductor layer in a variation of the first embodiment;

FIG. 5 is a schematic view of the structure of a semiconductor device in a variation of the first embodiment; and

FIG. 6 is a graph showing the drain current value for the impurity concentration of the third semiconductor layer.

### DETAILED DESCRIPTION OF PREFERRED EMBODIMENT

Specific embodiments will next be described by taking, as examples, a semiconductor device. However, the present invention is not limited to these embodiments.

### First Embodiment

### 1. Semiconductor Device

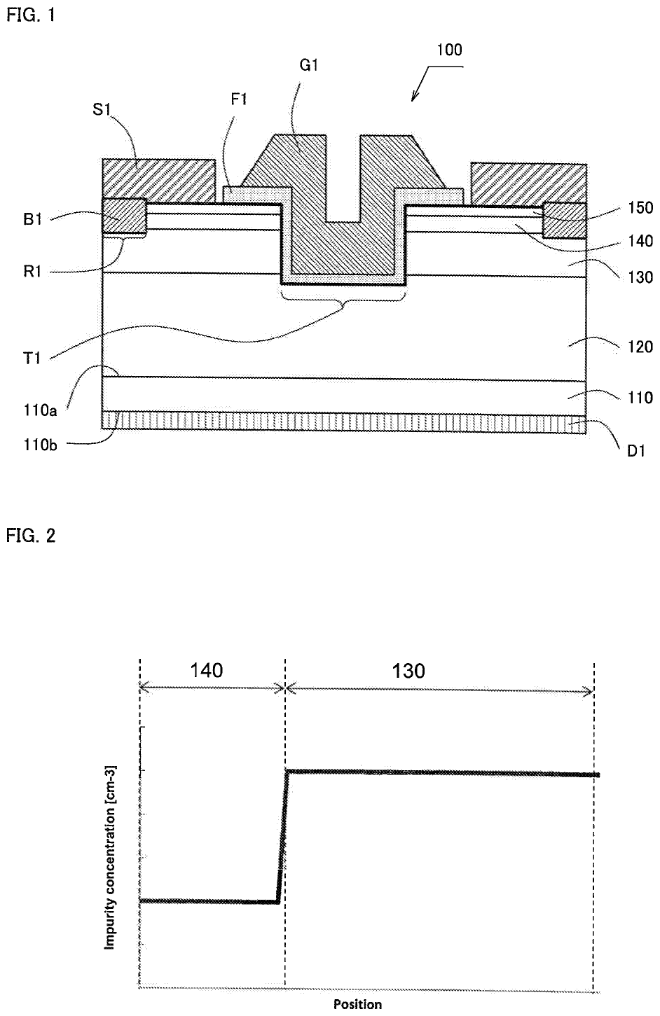

FIG. 1 is a schematic view of the structure of semiconductor device 100 according to a first embodiment. The semiconductor device 100 is a trench gate vertical MOSFET. In the present embodiment, the first conduction type is n-type conduction and the second conduction type is p-type conduction. Also the channel is n-channel whose conduction carriers are electrons and the MOSFET is normally off type, i.e., enhancement mode type. As shown in FIG. 1, the semiconductor device 100 includes a conductive substrate 110, a first semiconductor layer 120, a second semiconductor layer 130, a third semiconductor layer 140, a fourth semiconductor layer 150, a body electrode B1, a drain electrode D1, a source electrode S1, a gate electrode G1, and a gate insulating film F1. The respective layers from the first to the fourth semiconductor layers are sequentially deposited on the conductive substrate by MOCVD (metal organic chemical vapor deposition).

The conductive substrate 110 is a substrate formed of a conductive material. The conductive substrate 110 has a first surface 110a and a second surface 110b. The first surface 110a and the second surface 110b are surfaces opposite each other. The first surface 110a is a surface on which a semiconductor layer is formed. The second surface 110b is a surface on which a drain electrode D1 is formed. For example, the first surface 110a is a +c plane, and the second surface 110b is a −c plane. The conductive substrate 110 is, for example, a GaN substrate. The GaN substrate is often formed of n-GaN. The conductive substrate 110 may be formed of other conductive material. However, the conductive substrate 110 is preferably formed of Group III nitride semiconductor to form semiconductor layers thereon.

The first semiconductor layer 120 is formed on the first surface 110a of the conductive substrate 110. The first semiconductor layer 120 is a first conductive type Group III nitride semiconductor layer. The first semiconductor layer 120 is formed of, for example, n⁻-GaN. The thickness of the first semiconductor layer 120 is, for example, 5 μm to 20 μm. Here, the first conduction type is n-type, and the second conduction type is p-type.

The second semiconductor layer 130 is formed on the first semiconductor layer 120. The second semiconductor layer 130 is a second conductive type Group III nitride semiconductor layer. The second semiconductor layer 130 is formed of, for example, p-GaN. The thickness of the second semiconductor layer 130 is, for example, 0.5 μm to 1.5 μm.

The third semiconductor layer 140 is formed on the second semiconductor layer 130. The third semiconductor layer 140 is a second conductive type Group III nitride semiconductor layer. The third semiconductor layer 140 is formed of, for example, p⁻-GaN. As described later, the carrier concentration of the third semiconductor layer 140 is lower than the carrier concentration of the second semiconductor layer 130. The thickness of the third semiconductor layer 140 is, for example, 0.01 μm to 0.5 μm, preferably 0.01 μm to 0.4 μm.

The fourth semiconductor layer 150 is formed on the third semiconductor layer 140. The fourth semiconductor layer 150 is a first conductive type Group III nitride semiconductor layer. The fourth semiconductor layer 150 is formed of, for example, n⁺ GaN. The thickness of the fourth semiconductor layer 150 is, for example, 0.1 μm to 0.6 μm. Each of first to fourth layers has a uniform thickness and a flat surface.

The body electrode B1 is a first electrode to extract holes from the second semiconductor layer 130 and the third semiconductor layer 140. The body electrode B1 is formed in a recess R1. The recess R1 is a recessed part passing through the fourth semiconductor layer 150 and the third semiconductor layer 140, and reaching the middle of the second semiconductor layer 130. The body electrode B1 is in contact with the second semiconductor layer 130, the third semiconductor layer 140, the fourth semiconductor layer 150, and the source electrode S1.

The drain electrode D1 is a second electrode formed on the second surface 110b of the conductive substrate 110. As described before, the second surface 110b is, for example, a −c plane.

The source electrode S1 is a third electrode formed on the fourth semiconductor layer 150 and the body electrode B1. The source electrode S1 is in contact with the fourth semiconductor layer 150. Therefore, the source electrode S1 can inject electrons in the fourth semiconductor layer 150. The source electrode S1 is in contact with the body electrode B1. Therefore, the source electrode S1 and the body electrode B1 are equipotential.

The gate electrode G1 is a fourth electrode formed via the gate insulating film F1 in the trench T1. The trench T1 is a recessed part passing through the fourth semiconductor layer 150, the third semiconductor layer 140, and the second semiconductor layer 130, and reaching the middle of the first semiconductor layer 120. The gate electrode G1 extends toward the source electrode S1.

The gate insulating film F1 covers the trench T1. That is, the gate insulating film F1 covers the side surfaces of the fourth semiconductor layer 150, the third semiconductor layer 140, the second semiconductor layer 130, and the first semiconductor layer 120, and the top surface of the fourth semiconductor layer 150. Therefore, the gate insulating film F1 insulates the gate electrode G1 from the semiconductor layers.

The bottom end of the body electrode B1 is almost the same as the bottom end of the third semiconductor layer 140. A difference between the bottom end of the body electrode B1 and the bottom end of the third semiconductor layer 140 is 1 nm to 100 nm.

### 2. Impurity Concentration of Semiconductor Layer

The impurity concentration of the first semiconductor layer 120 is, for example, 5×10¹⁵ cm⁻³ to 2×10¹⁶ cm⁻³. Si is used as n-conduction type impurity in the present embodiment. The impurity concentration of the second semiconductor layer 130 is, for example, 6×10¹⁷ cm⁻³ to 2×10¹⁸ cm⁻³. The impurity concentration of the third semiconductor layer 140 is, for example, 5×10¹⁶ cm⁻³ to 3×10¹⁷ cm⁻³. Mg is used as p-conduction type impurity in the present embodiment. The impurity concentration of the fourth semiconductor layer 150 is, for example, 2×10¹⁸ cm⁻³ to 4×10¹⁸ cm⁻³. The impurity concentration is uniform in the entire area of the second semiconductor layer 130 and the third semiconductor layer 140, respectively. Also Si does not exist in the third semiconductor layer 140 in the present embodiment. These impurities are uniformly doped in the respective layers by impurity metal organic gas while the respective layers are growing.

As shown in FIG. 2, the impurity concentration of the third semiconductor layer 140 is lower than the impurity concentration of the second semiconductor layer 130. Moreover, the impurity concentration of the third semiconductor layer 140 is not more than 0.6 times and more preferably, 0.1 times the impurity concentration of the second semiconductor layer 130.

### 3. Characteristic of Semiconductor Device

### 3-1. Drain Current

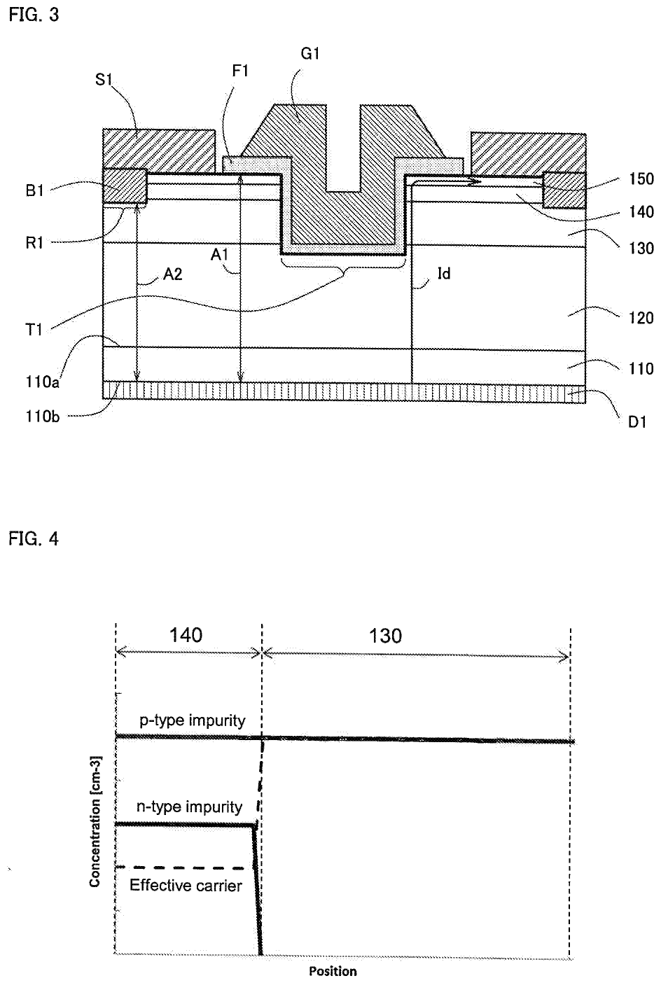

FIG. 3 shows a drain current Id flowing in the semiconductor device 100 of the first embodiment. When the potential of the gate electrode G1 reaches a threshold voltage, a current starts to flow from the drain electrode D1 toward the source electrode S1. This is the drain current Id. As shown in FIG. 3, the drain current Id passes from the drain electrode D1 through a channel induced in the vicinity of the gate electrode G1, and flows toward the source electrode S1. Carriers flowing in the cannel are electros supplied from the forth semiconductor layer 150.

### 3-2. On-Resistance and Breakdown Voltage

Therefore, as shown with an arrow A1 in FIG. 3, the on-resistance of the semiconductor device 100 is the electric resistance of layers provided between the source electrode S1 and the drain electrode D1. That is, the electric resistance between the conductive substrate 110 and the fourth semiconductor layer 150 bears the on-resistance of the semiconductor device 100.

As shown with an arrow A2 in FIG. 3, the breakdown voltage of the semiconductor device 100 is determined by the layers provided between the body electrode B1 and the drain electrode D1. A breakdown is caused by an electric field generated due to a reverse voltage applied to the pn junction between the second semiconductor layer 130 and the first semiconductor layer 120. Therefore, the conductive substrate 110, the first semiconductor layer 120, and the layer up to the middle of the second semiconductor layer 130 bears the breakdown voltage of the semiconductor device 100.

Thus, the conductive substrate 110, the first semiconductor layer 120, and the layer up to the middle of the second semiconductor layer 130 affect both on-resistance and breakdown voltage. On the other hand, the third semiconductor layer 140 and the fourth semiconductor layer 150 affect on-resistance, but do not affect breakdown voltage.

### 4. Effect of First Embodiment

The semiconductor device 100 has the third semiconductor layer 140 with an impurity concentration lower than that of the second semiconductor layer 130. In the third semiconductor layer 140 with a lower carrier (hole) concentration, electrons are more easily collected to a channel near the gate when the device is turned on, i.e., resistance of the channel is reduced. Accordingly, the semiconductor device 100 having a lower on-resistance is achieved by lowering the carrier (hole) concentration of the third semiconductor layer 140 which affects on-resistance, but does not affect breakdown voltage. Thus, the third semiconductor layer 140 with a lower carrier (hole) concentration makes the on-resistance of the semiconductor device 100 lower than that of the conventional semiconductor device.

In the first embodiment, since the carrier (hole) concentration of the third semiconductor layer 140 not affecting breakdown voltage is controlled, there is no risk of lowering the breakdown voltage. That is, the breakdown voltage is kept as high as that of the conventional semiconductor device.

### 5. Variation

### 5-1. Carrier Concentration

As shown in FIG. 4, the third semiconductor layer 140 may be doped with first conductive type (n-type) impurity and second conductive type (p-type) impurity. The n-type impurity is, for example, Si. The p-type impurity is, for example, Mg. However, the second conductive type impurity concentration of the third semiconductor layer 140 is higher than the first conductive type impurity concentration of the third semiconductor layer 140.

In this case, the effective carrier (hole) concentration of the third semiconductor layer 140 is lower than the hole concentration generated by only the second conductive type impurity concentration. The carrier (hole) concentration of the third semiconductor layer 140 may be lower than the carrier (hole) concentration of the second semiconductor layer 130. The carrier (hole) concentration of the third semiconductor layer 140 is not more than 0.6 times the carrier (hole) concentration of the second semiconductor layer 130.

5-2. Semiconductor Layer in Contact with Body Electrode

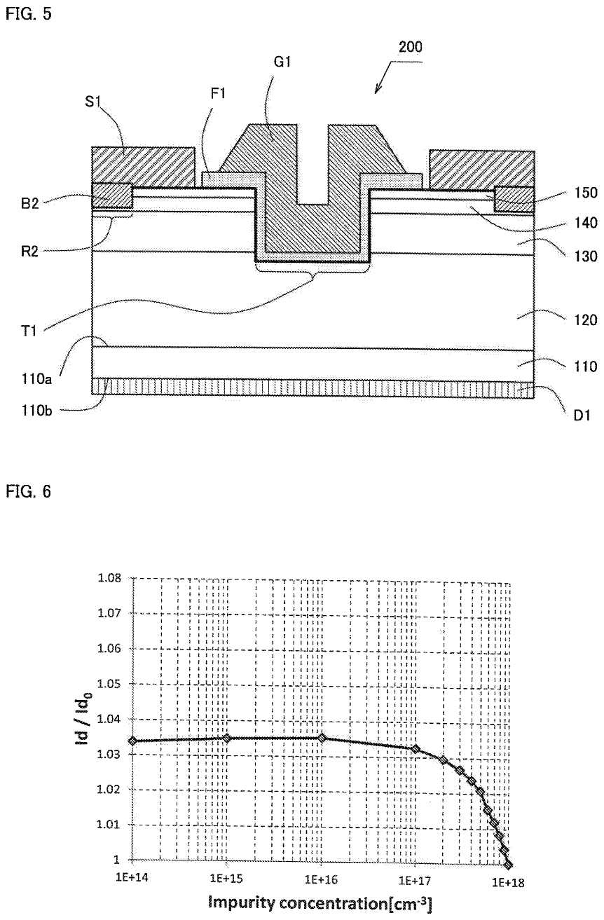

FIG. 5 is a schematic view of the structure of a semiconductor device 200 in a variation of the first embodiment. As shown in FIG. 5, in the semiconductor device 200, a body electrode B2 is not in contact with the second semiconductor layer 130, but is in contact with the third semiconductor layer 140 and the fourth semiconductor layer 150. A recess R2 is a recessed part passing through the fourth semiconductor layer 150, and reaching the middle of the third semiconductor layer 140.

Therefore, the body electrode B2 can extract holes from the third semiconductor layer 140, but cannot extract holes from the second semiconductor layer 130. The higher the impurity concentration, i.e., hole concentration in the layer with which the body electrode B2 is contacted, the higher the effect that the body electrode B1 extracts holes. Even in the case of FIG. 5, the body electrode B2 has some hole-extracting effect. In the semiconductor device 200 shown in FIG. 5, the breakdown voltage is slightly improved comparing to that of the semiconductor device 100 shown in FIG. 1. However, taking the hole-extracting effect into consideration, the semiconductor device 100 shown in FIG. 1 is preferable than the semiconductor device 200 shown in FIG. 5.

### 5-3. Body Electrode and Source Electrode

The body electrode B1 and the source electrode S1 may be independently formed. In this case, the body electrode B1 is not in contact with the source electrode S1.

### 5-4. Other Variation

The first conduction type may be p-type conduction and the second conduction type may be n-type conduction opposite to the first embodiment. Also the channel may be p-channel whose conduction carriers are holes. Also the MOSFET may be normally on type, i.e., depression mode type. In the first embodiment, FET is a trench gate vertical MOSFET, however, FET may be a vertical MOSFET not including a trench for the gate electrode. The conductive substrate may be any conductive semiconductor, e.g., Si, SiC. Any layers including Group III nitride semiconductor may exist between a substrate and the first semiconductor layer. The drain electrode may not be formed on the back surface of the conductive substrate but may be contacted with the first semiconductor layer.

The aforementioned variations may be combined with one another without any restriction.

### (Simulation)

The drain current Id was calculated by simulation with the Mg concentration of the third semiconductor layer 140 varied. A structure was adopted in which an n⁻ GaN layer (first semiconductor layer 120), a pGaN layer (second semiconductor layer 130), a p⁻ GaN layer (third semiconductor layer 140), and an n⁺ GaN layer (fourth semiconductor layer 150) were sequentially formed on a GaN substrate.

The thickness of the n⁻ GaN layer was 10 μm, and the impurity concentration of the n⁻ GaN layer was 1×10¹⁶ cm⁻³. The thickness of the pGaN layer was 0.9 μm, and the impurity concentration of the pGaN layer was 1×10¹⁸ cm⁻³. The thickness of the p⁻ GaN layer was 0.1 μm. The thickness of the n⁺ GaN layer was 0.3 μm, and the impurity concentration of the n⁺ GaN layer was 3×10¹⁸ cm⁻³. The impurity concentration of the p⁻ GaN layer was varied.

FIG. 6 is a graph showing the drain current value for the impurity concentration of the p⁻ GaN layer (third semiconductor layer 140). The horizontal axis in FIG. 6 indicates the impurity concentration of the p⁻ GaN layer. The vertical axis in FIG. 6 indicates the drain current Id/Id₀. Here, Id₀ is the drain current Id value when the impurity concentration of the p⁻ GaN layer was 1×10¹⁸ cm⁻³.

As shown in FIG. 6, when the impurity concentration of the p⁻ GaN layer (third semiconductor layer 140) is not more than 0.6 times the impurity concentration of the pGaN layer (second semiconductor layer 130), the drain current Id is larger by not less than 1% than the reference value. When the impurity concentration of the p⁻ GaN layer (third semiconductor layer 140) is not more than 0.1 times the impurity concentration of the pGaN layer (second semiconductor layer 130), the drain current Id is larger by not less than 3% than the reference value.

Thus, the lower the impurity concentration of the p⁻ GaN layer (third semiconductor layer 140), the more the drain current Id increases. When the impurity concentration of the p⁻ GaN layer (third semiconductor layer 140) is not more than 0.1 times the impurity concentration of the pGaN layer (second semiconductor layer 130), the drain current Id is saturated.

What is claimed is:

1. A semiconductor device including a gate electrode comprising:
a first semiconductor layer with a first conduction type;
a second semiconductor layer with a second conduction type formed on the first semiconductor layer, the second conduction type being opposite to the first conduction type;
a third semiconductor layer with the second conduction type formed on the second semiconductor layer;
a fourth semiconductor layer with the first conduction type formed on the third semiconductor layer, respective semiconductor layers from the first to the fourth semiconductor layer including Group III nitride semiconductor;
a first electrode contacted with at least one of the second semiconductor layer and the third semiconductor layer;
a second electrode for the first semiconductor layer; and
a third electrode for the fourth semiconductor layer,
wherein the second semiconductor layer and the third semiconductor layer induce or eliminate a channel by a gate voltage at side walls thereof near the gate electrode, and a carrier concentration of the third semiconductor layer is lower than a carrier concentration of the second semiconductor layer.

2. The semiconductor device including a gate electrode according to claim 1, the semiconductor device comprising:
a recess passing through the fourth semiconductor layer and reaching at least one of the second semiconductor layer and the third semiconductor layer,
wherein the first electrode is formed in the recess.

3. The semiconductor device including a gate electrode according to claim 1, the semiconductor device comprising:
a conductive substrate with first conduction type.

4. The semiconductor device including a gate electrode according to claim 3, wherein the first semiconductor layer is formed on the conductive substrate.

5. The semiconductor device including a gate electrode according to claim 1, wherein an impurity concentration of the third semiconductor layer is lower than an impurity concentration of the second semiconductor layer.

6. The semiconductor device including a gate electrode according to claim 1, the third semiconductor layer comprising:
a first conduction type impurity; and
a second conduction type impurity,
wherein the second conduction type impurity concentration is higher than the first conduction type impurity concentration.

7. The semiconductor device including a gate electrode according to claim 1, wherein the first electrode is in contact with both the second semiconductor layer and the third semiconductor layer.

8. The semiconductor device including a gate electrode according to claim 1, wherein the carrier concentration of the third semiconductor layer is not more than 0.6 times the carrier concentration of the second semiconductor layer.

9. The semiconductor device including a gate electrode according to claim 1, wherein the gate electrode is formed in a trench passing through the fourth semiconductor layer, the third semiconductor layer, and the second semiconductor layer, and reaching the middle of the first semiconductor layer.

10. The semiconductor device including a gate electrode according to claim 3, wherein the second electrode is contacted with at least one of on a back surface of the conductive substrate and the first semiconductor layer.

11. The semiconductor device including a gate electrode according to claim 1, wherein each of the third semiconductor layer and the second semiconductor layer has a uniform thickness and a flat surface.

12. The semiconductor device including a gate electrode according to claim 1, wherein the impurity concentration of the third semiconductor layer has a uniform concentration in an entire area of the third semiconductor layer.

13. The semiconductor device including a gate electrode according to claim 12, wherein a thickness of the third semiconductor layer is any value from 0.01 μm to 0.5 μm.
